(19) United States
(12) Patent Application Publication
(10) Pub. No.: US 2025/0234626 A1
(43) Pub. Date: Jul. 17, 2025

(54) NITRIDE SEMICONDUCTOR DEVICE

(71) Applicant: ROHM CO., LTD., Kyoto-shi (JP)

(72) Inventor: Hirotaka OTAKE, Kyoto-shi (JP)

(73) Assignee: ROHM CO., LTD., Kyoto-shi (JP)

(21) Appl. No.: 19/016,895

(22) Filed: Jan. 10, 2025

(30) Foreign Application Priority Data
Jan. 15, 2024 (JP) 2024-003965

(51) Int. Cl. H10D 64/27; H10D 30/47; H10D 62/85; H10D 64/00

(52) U.S. Cl. CPC H10D 64/519; H10D 62/8503; H10D 64/111; H10D 30/471

(57) ABSTRACT

A nitride semiconductor device includes a first passivation layer and a first field plate electrode arranged on the first passivation layer. The first passivation layer covers an electron supply layer, a gate layer, and a gate electrode. The first field plate electrode includes a plate body and a connector, which electrically connects the plate body and the source electrode. The plate body is at least partially arranged in a region between the gate electrode and the drain electrode in plan view, and extends in a Y-axis direction that is orthogonal to an X-axis direction in plan view. The connector is located above the gate electrode and between the plate body and the source electrode, has a width in the Y-axis direction, and extends in the X-axis direction to connect the plate body and the source electrode.

### CROSS-REFERENCE TO RELATED APPLICATION

This application is based upon and claims the benefit of priority from Japanese Patent Application No. 2024-003965, filed on Jan. 15, 2024, the entire contents of which are incorporated herein by reference.

### BACKGROUND

### 1. Field

The present disclosure relates to a nitride semiconductor device.

High-electron-mobility transistors (HEMTs) are now being commercialized. A HEMT uses a group III nitride semiconductor (hereafter, simply referred to as a nitride semiconductor), such as gallium nitride (GaN). Japanese Laid-Open Patent Publication No. 2017-73506 describes an example of such a transistor. A nitride semiconductor device having such a structure includes, for example, an electron transit layer, an electron supply layer formed on the electron transit layer and having a larger band gap than the electron transit layer, a gate layer formed on the electron transit layer and including an acceptor impurity, a gate electrode formed on the gate layer, and a passivation layer covering the electron supply layer, the gate layer, and the gate electrode. The nitride semiconductor device further includes a field plate electrode integrated with a source electrode. The field plate electrode extends from the source over the gate layer and the gate electrode to a drain electrode.

### BRIEF DESCRIPTION OF DRAWINGS

FIG. 1 is a schematic plan view of an exemplary nitride semiconductor device in accordance with one embodiment.

FIG. 2 is a schematic cross-sectional view of the nitride semiconductor device taken along line F2-F2 in FIG. 1.

FIG. 3 is a schematic cross-sectional view of the nitride semiconductor device taken along line F3-F3 in FIG. 1.

FIG. 4 is an enlarged, schematic plan view showing part of the nitride semiconductor device illustrated in FIG. 1.

FIG. 5 is an enlarged, schematic cross-sectional view showing part of the nitride semiconductor device illustrated in FIG. 2.

FIG. 6 is a schematic cross-sectional view showing a nitride semiconductor device of a comparative example.

FIG. 7 is a schematic cross-sectional view illustrating an exemplary manufacturing step of the nitride semiconductor device illustrated in FIG. 2.

FIG. 8 is a schematic cross-sectional view illustrating an exemplary manufacturing step following the step of FIG. 7.

FIG. 9 is a schematic cross-sectional view illustrating an exemplary manufacturing step following the step of FIG. 8.

FIG. 10 is a schematic cross-sectional view illustrating an exemplary manufacturing step following the step of FIG. 9.

FIG. 11 is a schematic cross-sectional view illustrating an exemplary manufacturing step following the step of FIG. 10.

FIG. 12 is a schematic cross-sectional view illustrating an exemplary manufacturing step following the step of FIG. 11.

FIG. 13 is a schematic cross-sectional view illustrating an exemplary manufacturing step following the step of FIG. 12.

FIG. 14 is a schematic plan view illustrating the exemplary manufacturing step of FIG. 13.

FIG. 15 is a schematic cross-sectional view illustrating an exemplary manufacturing step following the step of FIG. 13.

FIG. 16 is a schematic cross-sectional view illustrating an exemplary manufacturing step following the step of FIG. 15.

FIG. 17 is a schematic cross-sectional view illustrating an exemplary manufacturing step following the step of FIG. 16.

FIG. 18 is a schematic cross-sectional view illustrating an exemplary manufacturing step following the step of FIG. 17.

FIG. 19 is a schematic cross-sectional view showing a nitride semiconductor device of a modified example.

FIG. 20 is a schematic cross-sectional view showing a nitride semiconductor device of a modified example.

FIG. 21 is a schematic plan view showing a nitride semiconductor device of a modified example.

FIG. 22 is a schematic cross-sectional view of the nitride semiconductor device taken along line F22-F22 in FIG. 21.

FIG. 23 is a schematic cross-sectional view showing a nitride semiconductor device of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Several embodiments of a nitride semiconductor device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

This detailed description includes exemplary embodiments of devices, system, and methods in accordance with the present disclosure. Further, this detailed description is illustrative and is not intended to limit embodiments of the present disclosure or the application and use of the embodiments.

### Embodiment

### General Structure of Nitride Semiconductor Device

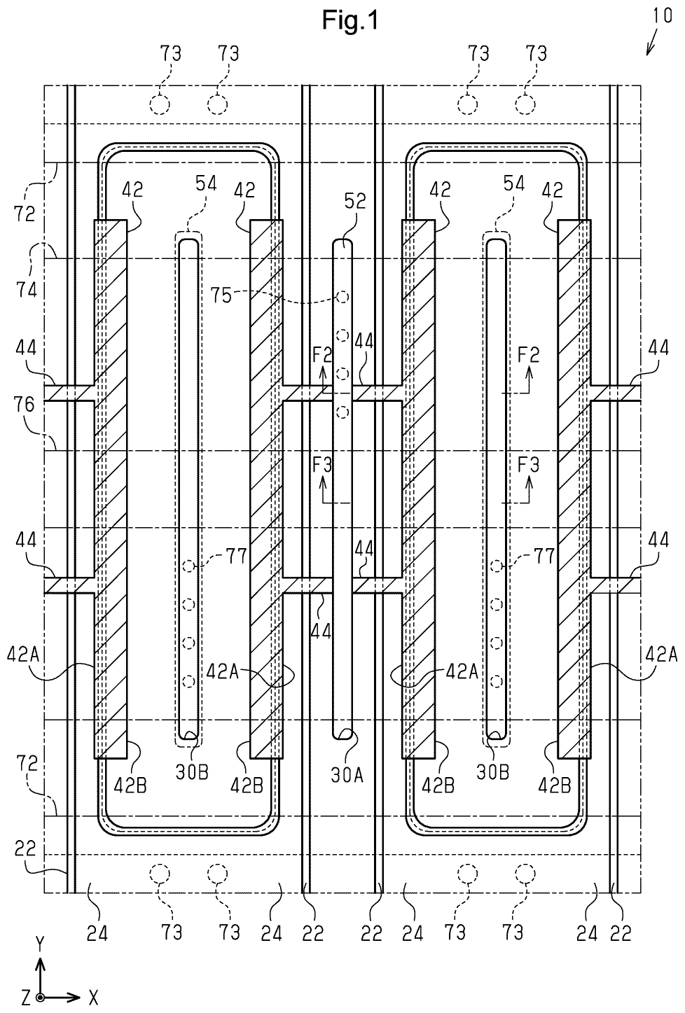

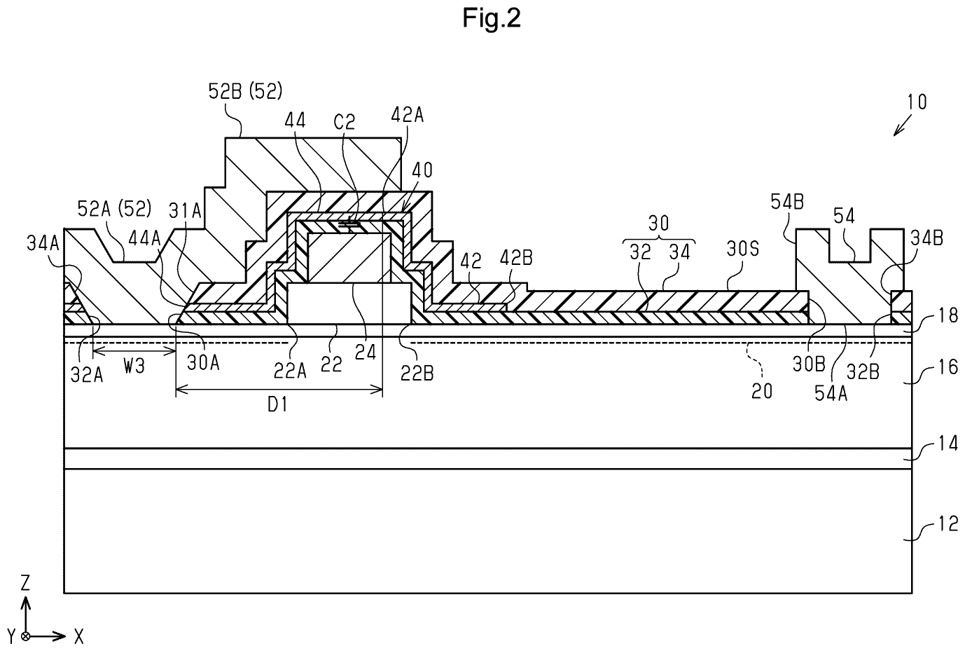

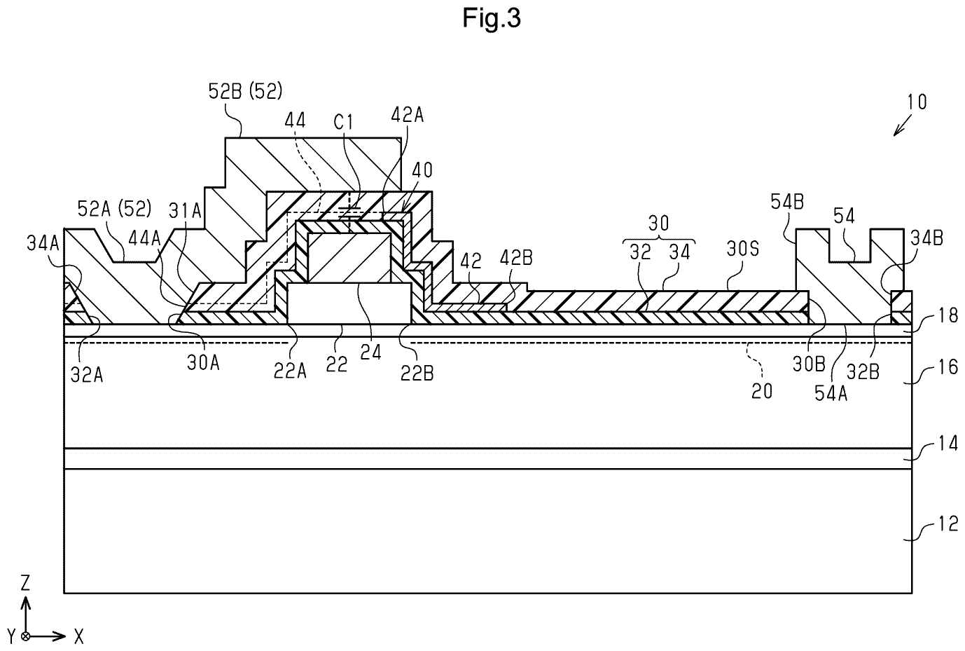

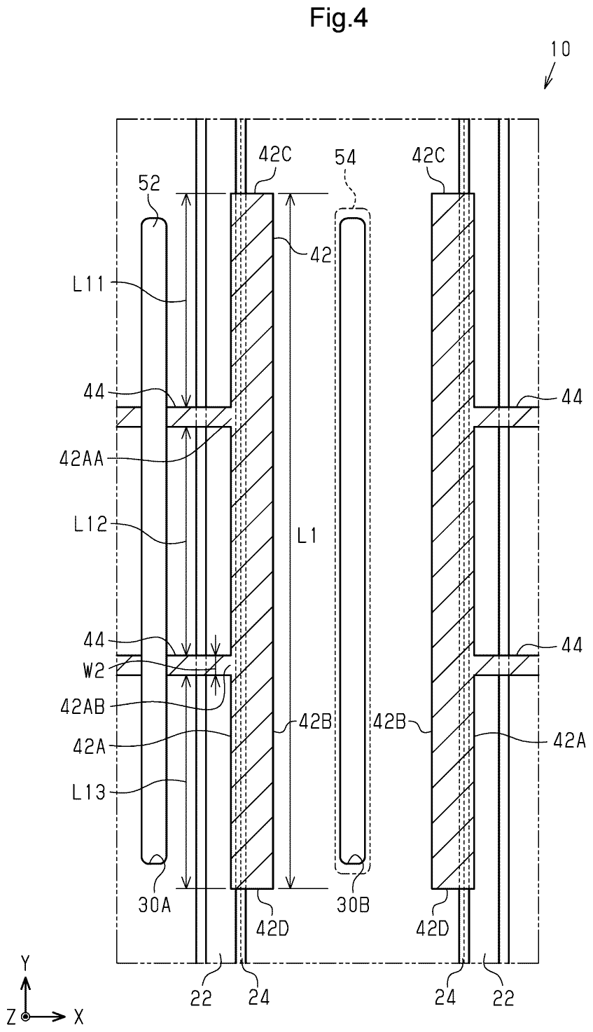

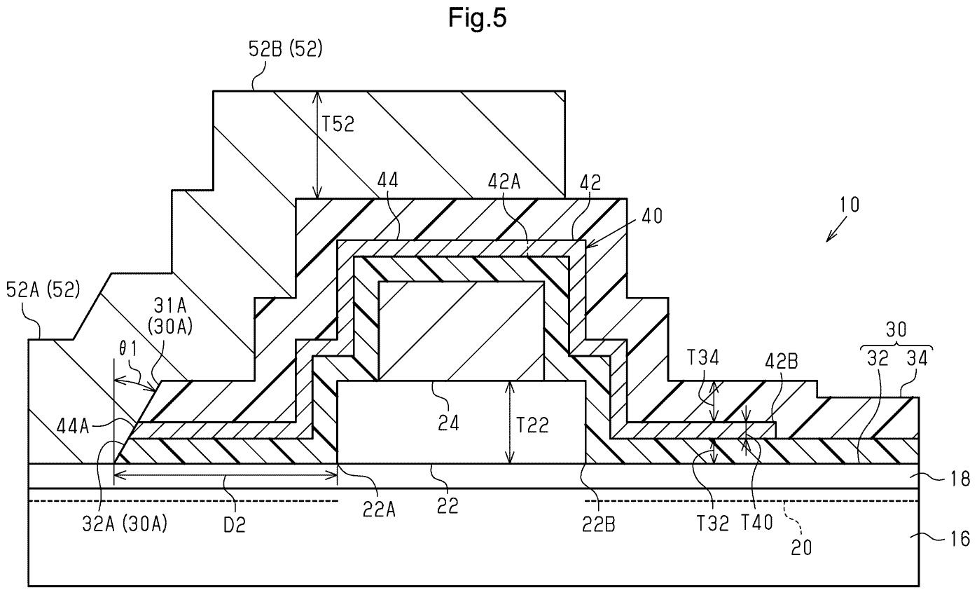

FIG. 1 is a schematic plan view of an exemplary nitride semiconductor device 10 in accordance with one embodiment. FIG. 2 is a schematic cross-sectional view of the nitride semiconductor device 10 taken along line F2-F2 in FIG. 1. FIG. 3 is a schematic cross-sectional view of the nitride semiconductor device 10 taken along line F3-F3 in FIG. 1. FIG. 4 is an enlarged, schematic plan view showing part of the nitride semiconductor device 10 illustrated in FIG. 1. FIG. 5 is an enlarged, schematic cross-sectional view showing part of the nitride semiconductor device 10 illustrated in FIG. 2. In FIGS. 1 to 5, unless otherwise indicated explicitly, the term “plan view” will refer to a view of the nitride semiconductor device 10 taken from above along the Z-axis. FIGS. 2 and 3 show a cross-sectional structure taken along an XZ plane.

In one example, the nitride semiconductor device 10 may be a high-electron-mobility transistor (HEMT) that uses GaN. The cross-sectional structure of the nitride semiconductor device 10 will now be described with reference to FIGS. 2 to 5. Then, the planar structure of the nitride semiconductor device 10 will be described with reference to FIG. 1.

As shown in FIG. 2, the nitride semiconductor device 10 may include a semiconductor substrate 12 and a buffer layer 14 arranged on the semiconductor substrate 12. The nitride semiconductor device 10 further includes an electron transit layer 16 and an electron supply layer 18 arranged on the electron transit layer 16.

The semiconductor substrate 12 may be formed from silicon (Si), silicon carbide (SiC), GaN, sapphire, or other substrate materials. In one example, the semiconductor substrate 12 may be a Si substrate. The semiconductor substrate 12 may have a thickness, for example, in a range from 100 μm to 1500 μm, inclusive.

The buffer layer 14 may include one or more nitride semiconductor layers. The electron transit layer 16 is arranged on the buffer layer 14. In one example, the buffer layer 14 may be composed of any material that facilitates epitaxial growth of the electron transit layer 16.

For example, the buffer layer 14 may include at least one of an aluminum nitride (AlN) layer, an aluminum gallium nitride (AlGaN) layer, and a graded AlGaN layer including different aluminum (Al) compositions. For example, the buffer layer 14 may be a single AlN layer, a single AlGaN layer, a layer having an AlGaN/GaN superlattice structure, a layer having an AlN/AlGaN superlattice structure, or a layer having an AlN/GaN superlattice structure. To reduce leakage current in the buffer layer 14, part of the buffer layer 14 may include an impurity so that the buffer layer 14 becomes semi-insulative. In such a case, the impurity may be, for example, carbon (C) or iron (Fe), and the concentration of the impurity may be, for example, 4×10¹⁶ cm⁻³.

The electron transit layer 16 is composed of a semiconductor nitride. The electron transit layer 16 may be, for example, a GaN layer. The electron transit layer 16 may have a thickness, for example, in a range from 0.5 μm to 2 μm, inclusive. To reduce leakage current in the electron transit layer 16, part of the electron transit layer 16 may include an impurity so that regions other than the outermost layer of the electron transit layer 16 are semi-insulative. In this case, the impurity may be, for example, C. The impurity concentration in the electron transit layer 16 may be, for example, 1×10¹⁶ cm⁻³ or greater.

The electron supply layer 18 is composed of a nitride semiconductor having a larger band gap than the electron transit layer 16. The electron supply layer 18 may be, for example, an AlGaN layer. The band gap becomes larger as the Al composition increases. Thus, the electron supply layer 18, which is an AlGaN layer, has a larger band gap than the electron transit layer 16, which is a GaN layer. In one example, the electron supply layer 18 is composed of Al_{X}Ga_{(1-X)}N, where the Al composition X is 0.1<X<0.4, and more preferably, 0.1<X<0.3. The electron supply layer 18 may have a thickness in a range from 5 nm to 20 nm, inclusive. In one example, the electron supply layer 18 may have a thickness of 8 nm or greater.

The electron transit layer 16 and the electron supply layer 18 may be composed of nitride semiconductors having different lattice constants. Thus, the nitride semiconductor of the electron transit layer 16 (e.g., GaN) and the nitride semiconductor of the electron supply layer 18 (e.g., AlGaN) form a lattice-mismatched heterojunction. The spontaneous polarization of the electron transit layer 16 and the electron supply layer 18 and the piezoelectric polarization caused by crystal distortion in the proximity of the heterojunction interface result in the energy level of the conduction band of the electron transit layer 16 being lower than the Fermi level in the proximity of the heterojunction interface. Thus, two-dimensional electron gas (2DEG) 20 spreads in the electron transit layer 16 at a location proximate to the heterojunction interface of the electron transit layer 16 and the electron supply layer 18 (e.g., distanced by approximately a few nanometers from interface). The sheet carrier density of the 2DEG 20 generated in the electron transit layer 16 may be increased by increasing at least one of the Al composition and the thickness of the electron supply layer 18.

### Gate Layer and Gate Electrode

The nitride semiconductor device 10 further includes a gate layer 22 formed on the electron supply layer 18 and a gate electrode 24 formed on the gate layer 22. The gate layer 22 may be formed on part of the electron supply layer 18.

The gate layer 22 may have a tetragonal cross section taken along an XZ plane in FIGS. 2 and 3. The gate layer 22 may have a trapezoidal cross section taken along the XZ plane. The gate layer 22 may have a thickness T22, for example, in a range from 60 nm to 200 nm, inclusive.

The gate layer 22 is composed of a nitride semiconductor containing an acceptor impurity. The gate layer 22 may have a smaller band gap than the electron supply layer 18. The gate layer 22 may be composed of any material having a smaller band gap than the electron supply layer 18, which is an AlGaN layer. The gate layer 22 may be a gallium nitride layer (p-type GaN layer) doped with an acceptor impurity. The acceptor impurity may contain at least one of zinc (Zn), magnesium (Mg), and carbon (C). The maximum concentration of the acceptor impurity in the gate layer 22 may be in a range from 7×10¹⁸ cm⁻³ to 1×10²⁰ cm⁻³, inclusive. In one example, the gate layer 22 may be GaN containing at least one of Mg and Zn as an impurity.

The acceptor impurity in the gate layer 22 raises the energy level of the electron transit layer 16 and the electron supply layer 18. Thus, the energy level of the conduction band of the electron transit layer 16 is substantially the same as or greater than the Fermi level in the proximity of the heterojunction interface between the electron transit layer 16 and the electron supply layer 18 in the region underneath the gate layer 22. Accordingly, at zero-bias when voltage is not applied to the gate electrode 24, the 2DEG 20 is not formed in the electron transit layer 16 at a region underneath the gate layer 22. The 2DEG 20 is formed in the electron transit layer 16 at regions other than the region underneath the gate layer 22.

In this manner, the gate layer 22, which is doped with the acceptor impurity, depletes the 2DEG 20 at the region underneath the gate layer 22. This results in the transistor being normally off. The application of an appropriate on-voltage to the gate electrode 24 will form a channel with the 2DEG 20 in the electron transit layer 16 at the region underneath the gate electrode 24 and electrically connect the source and drain.

The gate electrode 24 includes one or more metal layers. In one example, the gate electrode 24 is formed by a titanium nitride (TiN) layer. In another example, the gate electrode 24 includes a first metal layer of Ti and a second metal layer of TiN arranged on the first metal layer. The gate electrode 24 and the gate layer 22 may form a Schottky junction. The gate electrode 24 may be formed in a smaller region than the gate layer 22 in plan view. The gate electrode 24 may have a thickness, for example, in a range from 50 nm to 200 nm, inclusive.

The nitride semiconductor device 10 further includes a passivation layer 30 covering the electron supply layer 18, the gate layer 22, and the gate electrode 24. The passivation layer 30 may be composed of, for example, one of silicon nitride (SiN), silicon dioxide (SiO₂), silicon oxynitride (SiON), alumina (Al₂O₃), AlN, and aluminum oxynitride (AlON). The passivation layer 30 may have a thickness, for example, in a range from 80 nm to 150 nm, inclusive.

The passivation layer 30 includes a source opening 30A and a drain opening 30B separated from each other in the X-axis direction. In this specification, the X-axis direction will be referred to as the first direction, and the Y-axis direction will be referred to as the second direction. Accordingly, the second direction is orthogonal to the first direction in plan view. The gate layer 22 is located between the source opening 30A and the drain opening 30B. More specifically, the gate layer 22 located between the source opening 30A and the drain opening 30B is closer to the source opening 30A than the drain opening 30B.

### Source Electrode and Drain Electrode

The nitride semiconductor device 10 includes a source electrode 52 and a drain electrode 54. The source electrode 52 contacts the electron supply layer 18 in the source opening 30A. The source opening 30A of the passivation layer 30 exposes part of the electron supply layer 18. The source electrode 52 contacts the electron supply layer 18 exposed by the source opening 30A. The source electrode 52 is in ohmic contact with the 2DEG underneath the electron supply layer 18.

The drain electrode 54 contacts the electron supply layer 18 in the drain opening 30B. The drain opening 30B of the passivation layer 30 exposes part of the electron supply layer 18. The drain electrode 54 contacts the electron supply layer 18 exposed by the drain opening 30B. The drain electrode 54 is in ohmic contact with the 2DEG underneath the electron supply layer 18.

The source electrode 52 and the drain electrode 54 are located at opposite sides of the gate layer 22 on the upper surface of the electron supply layer 18. The source electrode 52 and the drain electrode 54 may each be formed by one or more metal layers. For example, the source electrode 52 and the drain electrode 54 may be formed by any combination of two or more of a Ti layer, a TiN layer, an Al layer, an AlSiCu layer, and an AlCu layer.

The source electrode 52 includes a contact 52A filling the source opening 30A, and an extension 52B formed integrally with the contact 52A and located proximate to the source opening 30A in plan view. The extension 52B is located on the passivation layer 30.

The drain electrode 54 includes a contact 54A filling the drain opening 30B, and an extension 54B formed integrally with the contact 54A and located proximate to the drain opening 30B in plan view. The extension 54B is located on the passivation layer 30. The extension 52B of the source electrode 52 may have a thickness T52 of, for example, 350 nm. The extension 54B of the drain electrode 54 may have a thickness T52 of, for example, 350 nm.

### Passivation Layer

The passivation layer 30 includes a first passivation layer 32 and a second passivation layer 34. The first passivation layer 32 is arranged on the electron supply layer 18. The first passivation layer 32 covers the electron supply layer 18, the gate layer 22, and the gate electrode 24. In one example, the first passivation layer 32 is in contact with the electron supply layer 18, the gate layer 22, and the gate electrode 24.

The second passivation layer 34 is arranged on the first passivation layer 32. The second passivation layer 34 covers the first passivation layer 32. The second passivation layer 34 is in contact with the first passivation layer 32.

The first passivation layer 32 and the second passivation layer 34 may be composed of the same material. The first passivation layer 32 and the second passivation layer 34 may be composed of different materials.

The first passivation layer 32 has a thickness T32, for example, in a range from 30 nm to 60 nm, inclusive. In one example, the thickness T32 of the first passivation layer 32 may be 40 nm. The second passivation layer 34 may be thicker than the first passivation layer 32. The second passivation layer 34 may have a thickness T34, for example, in a range from 50 nm to 100 nm, inclusive. In one example, the thickness T34 of the second passivation layer 34 may be 80 nm.

The source opening 30A of the passivation layer 30 extends through the first passivation layer 32 and the second passivation layer 34. The source opening 30A includes a first source opening 32A of the first passivation layer 32 and a second source opening 34A of the second passivation layer 34.

In one example, the source opening 30A may be formed so that the width of the source opening 30A increases from the electron supply layer 18 toward an upper surface 30S of the passivation layer 30. The passivation layer 30 includes a wall surface 31A defining the source opening 30A.

As shown in FIG. 5, the wall surface 31A of the source opening 30A includes an inclined surface that is inclined with respect to an XY plane that is orthogonal to the Z-axis direction, which is the thickness direction of the first passivation layer 32 and the second passivation layer 34. In other words, the wall surface 31A includes an inclined surface that is inclined with respect to the Z-axis direction. The inclination angle θ1 of the wall surface 31A of the source opening 30A with respect to the Z-axis direction may be in a range from 20 degrees to 60 degrees, inclusive. In one example, the inclination angle θ1 may be greater than or equal to 30 degrees.

As shown in FIGS. 2 and 3, the drain opening 30B of the passivation layer 30 extends through the first passivation layer 32 and the second passivation layer 34. The drain opening 30B includes a first drain opening 32B of the first passivation layer 32 and a second drain opening 34B of the second passivation layer 34. In one example, the drain opening 30B may be formed so that the width of the drain opening 30B is the same from the electron supply layer 18 to the upper surface 30S of the passivation layer 30.

### Field Plate Electrode

As shown in FIGS. 1 to 5, the nitride semiconductor device 10 includes a first field plate electrode 40.

As shown in FIGS. 2, 3, and 5, the first field plate electrode 40 is embedded in the passivation layer 30. The passivation layer 30 includes the first passivation layer 32 and the second passivation layer 34 on the first passivation layer 32. The first field plate electrode 40 is located between the first passivation layer 32 and the second passivation layer 34. The first field plate electrode 40 is arranged on the first passivation layer 32 and covered by the second passivation layer 34.

As shown in FIGS. 1 to 5, the first field plate electrode 40 includes a plate body 42 and a connector 44. In FIG. 3, the connector 44 is shown in broken lines. The plate body 42 is separated from the source electrode 52 in the X-axis direction. The plate body 42 is at least partially arranged in a region between the gate layer 22 and the drain electrode 54 in plan view. Further, the plate body 42 extends in the Y-axis direction, which is orthogonal to the X-axis direction, in plan view. In one example, the plate body 42 is rectangular and longer in the Y-axis direction than in the X-axis direction. In one example, the plate body 42 may be longer than the source opening 30A in the Y-axis direction. Further, in one example, the plate body 42 may be longer than the drain opening 30B in the Y-axis direction. As shown in FIG. 4, in the Y-axis direction, the plate body 42 may have a length L1 in a range from 400 μm to 1000 μm, inclusive.

As shown in FIGS. 2, 3, and 5, the plate body 42 is at least partially arranged in a region between the gate layer 22 and the drain electrode 54 in plan view and extends in the Y-axis direction, which is orthogonal to the X-axis direction, in plan view. As shown in FIG. 2, the source opening 30A, in which the source electrode 52 is formed, and the plate body 42 are separated in one example by a distance D1 of approximately 1 μm.

The connector 44 is arranged between the plate body 42 and the source electrode 52. The connector 44 electrically connects the plate body 42 and the source electrode 52. The connector 44 extends from the plate body 42 over the gate electrode 24 and to the source electrode 52. The plate body 42 is located above the gate electrode 24 and extends in the X-axis direction. In plan view, the connector 44 has an area that is less than an area of the plate body 42. The area of the connector 44 may be less than or equal to one-tenth of the area of the plate body 42. The connector 44 has a width W2 that is the length of the connector 44 in the Y-axis direction. The width W2 of the connector 44 is less than the length L1 of the plate body 42. The width W2 of the connector 44 may be less than or equal to one-fiftieth of the length L1 of the plate body 42. The width W2 of the connector 44 may be in a range from 5 μm to 10 μm, inclusive.

As shown in FIG. 5, the connector 44 is exposed in the source opening 30A of the passivation layer 30. The passivation layer 30 includes the wall surface 31A, which defines the source opening 30A. The connector 44 is exposed from the wall surface 31A. The passivation layer 30 includes the wall surface 31A from which the connector 44 is exposed. The wall surface 31A defines the source opening 30A. The source opening 30A includes the wall surface 31A from which the connector 44 is exposed. The wall surface 31A of the source opening 30A includes the inclined surface inclined with respect to an XY plane that is orthogonal to the Z-axis direction, which is the thickness direction of the first passivation layer 32 and the second passivation layer 34. The connector 44 includes a connector end surface 44A connected to the source electrode 52. The connector end surface 44A is inclined in conformance with the wall surface 31A of the source opening 30A in the passivation layer 30.

As shown in FIGS. 4 and 5, in the X-axis direction, the plate body 42 includes a first end 42A and a second end 42B at the opposite side of the first end 42A. The first end 42A is the end of the plate body 42 that is located closer to the source electrode 52. The second end 42B is the end of the plate body 42 that is located closer to the drain electrode 54.

The first end 42A of the plate body 42 may be located on the gate layer 22. The second end 42B of the plate body 42 may be located between the gate layer 22 and the drain electrode 54 in plan view. The plate body 42 overlaps part of the gate layer 22. The plate body 42 covers a second end 22B of the gate layer 22 in plan view. The plate body 42 does not cover a first end 22A of the gate layer 22 in plan view.

The first end 42A of the plate body 42 may be located on the gate electrode 24. The plate body 42 overlaps part of the gate layer 22. The plate body 42 overlaps part of the gate electrode 24. The area of the region in which the plate body 42 and the gate electrode 24 overlap may be smaller than the area of the region in which the plate body 42 and the gate electrode 24 do not overlap in plan view.

As shown in FIG. 4, the nitride semiconductor device 10 may include more than one connector 44 for one plate body 42. That is, more than one connector 44 may be connected to each plate body 42. The connector 44 is connected to the first end 42A of the plate body 42. Thus, each plate body 42 is electrically connected by more than one connector 44 to the source electrode 52. In one example, each plate body 42 is electrically connected by two connectors 44 to the source electrode 52. The two connectors 44 result in the potential at the plate body 42 being the same as the potential at the source electrode 52.

As shown in FIG. 4, in the Y-axis direction, the plate body 42 includes a third end 42C and a fourth end 42D at the opposite side of the third end 42C. Further, the plate body 42 includes a first connecting portion 42AA and a second connecting portion 42AB connected to the two connectors 44. In one example, the two connectors 44 are connected to the plate body 42 so that the length L11 between the third end 42C and the first connecting portion 42AA, the length L12 between the first connecting portion 42AA and the second connecting portion 42AB, and the length L13 between the second connecting portion 42AB and the fourth end 42D are equal.

As shown in FIG. 5, in the X-axis direction, the gate layer 22 includes the first end 22A and the second end 22B at the opposite side of the first end 22A. The first end 22A is the end of the gate layer 22 located toward the source electrode 52. The second end 22B is the end of the gate layer 22 located toward the drain electrode 54. The distance D2 between the first end 22A of the gate layer 22 and the source opening 30A in the X-axis direction may be in a range from 0.3 μm to 0.6 μm, inclusive. As shown in FIG. 2, in the X-axis direction, the source opening 30A may have a minimum width W3 of 1 μm or less.

### Planar Layout of Nitride Semiconductor Device

With reference to FIG. 1, one example of the planar layout of the nitride semiconductor device 10 will now be described. In FIG. 1, the gate electrode 24, the first field plate electrode 40, and part of the source electrode 52 (part of the source electrode 52 located inside source opening 30A) are depicted with solid lines. The drain electrode 54 is depicted with broken lines. Further, the source opening 30A and the drain opening 30B of the passivation layer 30 are depicted with solid lines, while other portions are shown in transparency.

As shown in FIG. 1, the nitride semiconductor device 10 includes, in an element region, transistor elements, each having the HEMT structure of the nitride semiconductor device 10. FIG. 1 only shows transistors elements arranged next to each other in the X-axis direction. The transistor elements may be arranged next to one another in both the X-axis direction and the Y-axis direction.

The drain electrode 54 is provided for each transistor element. The drain electrode 54 extends in the Y-axis direction in plan view. The source electrode 52, for example, surrounds each drain electrode 54 in plan view. In the example of FIG. 1, the source electrode 52 is formed continuously in the X-axis direction over the transistor elements that are adjacent to one another in the X-axis direction but may instead be separated into a number of portions in the X-axis direction.

The gate layer 22 and the gate electrode 24 are provided for each transistor element. Each gate layer 22 and each gate electrode 24 has a closed shape and surrounds one of the drain electrodes 54 in plan view.

The first field plate electrode 40 is provided for each transistor element. The first field plate electrode 40 includes the plate body 42, which is separated from the source electrode 52 in the X-axis direction, and the connector 44, which electrically connects the plate body 42 and the source electrode 52. The plate body 42 is at least partially arranged in a region between the gate layer 22 and the drain electrode 54 in plan view and extends in the Y-axis direction. The plate body 42 may have a closed shape surrounding the drain electrode 54.

The nitride semiconductor device 10 may include a gate interconnect 72, a source interconnect 74, and a drain interconnect 76. In FIG. 1, the gate interconnect 72, the source interconnect 74, and the drain interconnect 76 are depicted with single-dashed lines. The gate interconnect 72, the source interconnect 74, and the drain interconnect 76 are located above the source electrode 52 and the drain electrode 54 in the Z-axis direction. The gate interconnect 72, the source interconnect 74, and the drain interconnect 76 extend in the X-axis direction. The gate interconnect 72, the source interconnect 74, and the drain interconnect 76 are separated from one another in the Y-axis direction.

The gate interconnect 72 may be separated in the Y-axis direction from the drain electrode 54, the source opening 30A, and the drain opening 30B. The gate interconnect 72 may be electrically connected to the gate electrode 24 by a via interconnect 73. The source interconnect 74 and the drain interconnect 76 may be arranged to overlap, in the Y-axis direction, the drain electrode 54, the source opening 30A, and the drain opening 30B. The source interconnect 74 may be electrically connected to the source electrode 52 by a via interconnect 75. The drain interconnect 76 may be electrically connected to the drain electrode 54 by a via interconnect 77. In FIG. 1, the via interconnects 73, 75, and 77 are depicted with broken lines. The planar layout of the nitride semiconductor device 10 is not limited to the example shown in FIG. 1. The nitride semiconductor device 10 may have any other structure.

### Operation of Embodiment

### Comparative Example

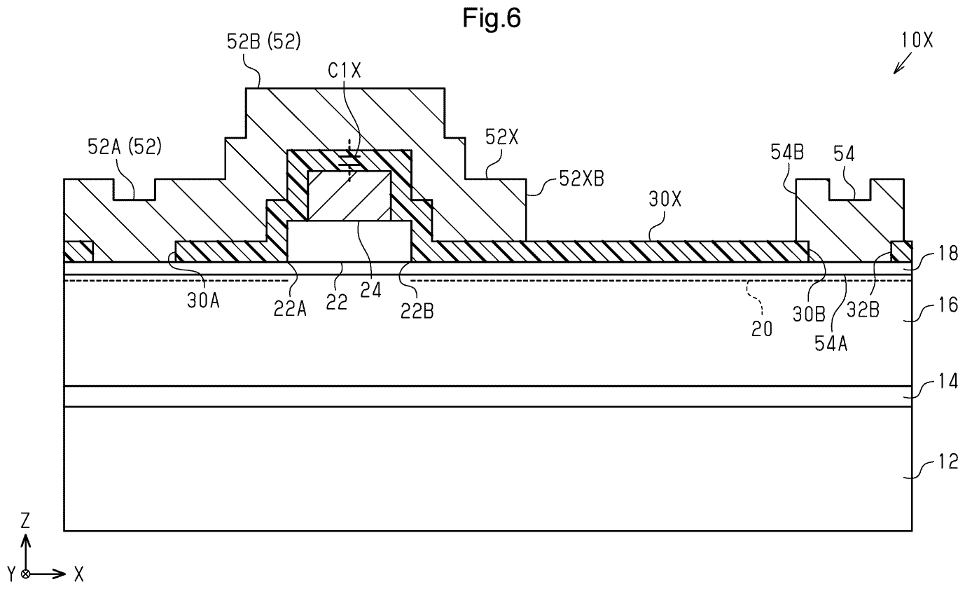

FIG. 6 is a schematic cross-sectional view of a nitride semiconductor device 10X, which is an example compared with the nitride semiconductor device 10 in accordance with the above embodiment. The structure of FIG. 6 is an example compared with the structure of FIGS. 2 and 3. In the comparative example of the nitride semiconductor device 10X, the same reference characters are given to those components that are the same as the corresponding components in the nitride semiconductor device 10 of the embodiment.

The nitride semiconductor device 10X of the comparative example includes a passivation layer 30X that covers the electron supply layer 18, the gate layer 22, and the gate electrode 24. The nitride semiconductor device 10X of the comparative example includes a source field plate electrode 52X formed integrally with the source electrode 52. The source field plate electrode 52X is arranged on the passivation layer 30X to entirely cover the gate electrode 24 and the gate layer 22. The source field plate electrode 52X includes an end 52XB located toward the drain electrode 54. The end 52XB is located between the drain electrode 54 and the gate layer 22 in plan view. When a high voltage is applied between the source and drain in a state in which the gate-source voltage is 0 V, the source field plate electrode 52X expands a depletion layer toward the 2DEG 20 located underneath the source field plate electrode 52X and mitigates electric field concentration in the vicinity of the second end 22B of the gate layer 22.

In the nitride semiconductor device 10X of the comparative example, in order to reduce the on resistance, for example, the distance between the source electrode 52 and the drain electrode 54 may be shortened. In this case, to mitigate electric field concentration that occurs when decreasing the distance between the source electrode 52 and the drain electrode 54, the passivation layer 30X, which extends under the source field plate electrode 52X and above the gate layer 22 and the gate electrode 24, has to be reduced in thickness. The source field plate electrode 52X and the gate electrode 24 located at opposite sides of the passivation layer 30X form a parasitic capacitor C1X. When the passivation layer 30X is reduced in thickness, the capacitance of the parasitic capacitor C1X increases. An increase in the capacitance of the parasitic capacitor C1X lengthens the charging and discharging time of the parasitic capacitor C1X. That is, the time is lengthened during which the gate voltage at the gate electrode 24 rises and falls (transition period) and thereby increases energy loss.

The source electrode 52 and the drain electrode 54 are formed by selectively etching a metal layer formed on the passivation layer 30X. The metal layer used to form the source electrode 52 and the drain electrode 54 has a thickness of, for example, 350 nm. During manufacturing, when performing etching to electrically disconnect the source electrode 52 and the drain electrode 54, the passivation layer 30X is subject to over-etching. Thus, due to differences produced during the manufacturing process, when etching the thick metal layer, the passivation layer 30X may become too thin. In this case, if the passivation layer 30X becomes thinner than desired, the insulating property of the passivation layer 30X may be adversely affected.

Nitride Semiconductor Device in Accordance with Present Embodiment

The nitride semiconductor device 10 in accordance with the present embodiment includes the electron transit layer 16 composed of a nitride semiconductor. The electron supply layer 18 is arranged on the electron transit layer 16 and composed of a nitride semiconductor having a larger band gap than the electron transit layer 16. The gate layer 22 is arranged on the electron supply layer 18 and composed of a nitride semiconductor containing an acceptor impurity. The gate electrode 24 is arranged on the gate layer 22. The first passivation layer 32 covers the electron supply layer 18, the gate layer 22, and the gate electrode 24, and includes a first source opening 32A and a first drain opening 32B separated from each other in the X-axis direction and located at opposite sides of the gate layer 22 in the X-axis direction. The source electrode 52 contacts the electron supply layer 18 in the first source opening 32A. The drain electrode 54 contacts the electron supply layer 18 in the first drain opening 32B. The first field plate electrode 40 is arranged on the first passivation layer 32. The second passivation layer 34 covers the first passivation layer 32 and the first field plate electrode 40.

The first field plate electrode 40 includes the plate body 42 separated from the source electrode 52 in the X-axis direction, and the connector 44 electrically connecting the plate body 42 and the source electrode 52. The plate body 42 is at least partially arranged in a region between the gate layer 22 and the drain electrode 54 in plan view and extends in the Y-axis direction that is orthogonal to the X-axis direction. The plate body 42 of the first field plate electrode 40, which is arranged on the first passivation layer 32, covers the second end 22B of the gate layer 22 located toward the drain electrode 54. Thus, the plate body 42 mitigates electric field concentration in the vicinity of the end of the gate layer 22. In the nitride semiconductor device 10 of the present embodiment, the distance

between the source electrode 52 and the drain electrode 54 may be shortened to reduce the on resistance. The plate body 42 of the first field plate electrode 40 is arranged on the first passivation layer 32, which covers the electron supply layer 18, the gate layer 22, and the gate electrode 24. The first passivation layer 32 is thinner than the second passivation layer 34, which forms the passivation layer 30 with the first passivation layer 32. This allows for mitigation of electric field concentration, which occurs when reducing the distance between the source electrode 52 and the drain electrode 54.

As shown in FIG. 5, the first field plate electrode 40 has a thickness T40 that is less than the thickness T32 of the first passivation layer 32. Further, the thickness T40 of the first field plate electrode 40 is less than the thickness T52 of the source electrode 52. Thus, the decrease in thickness of the first passivation layer 32 resulting from over-etching when forming the first field plate electrode 40 will be much less compared to the decrease in thickness of the passivation layer 30X when forming the source electrode 52 in the nitride semiconductor device 10X of the comparative example. This maintains the insulating property of the first passivation layer 32, that is, the passivation layer 30.

The first field plate electrode 40 includes the connector 44. The connector 44 is located above the gate electrode 24 and between the plate body 42 and the source electrode 52, has a width in the Y-axis direction, and extends in the X-axis direction to connect the plate body 42 and the source electrode 52. The width of the connector 44 is less than the length of the plate body 42 in the Y-axis direction. Thus, the first field plate electrode 40 faces the gate electrode 24 over a smaller area than in the nitride semiconductor device 10X of the comparative example in which the plate body 42 and the source electrode 52 are connected in the same manner. A parasitic capacitor C2 has a capacitance corresponding to the area of the connector 44 facing the gate electrode 24. The passivation layer 30 is increased in thickness so that a parasitic capacitor C1 formed between the gate electrode 24 and the source electrode 52 has a capacitance that is smaller than the capacitance of the parasitic capacitor C1X in the nitride semiconductor device 10X of the comparative example. The combined capacitance of the parasitic capacitors C1 and C2 is smaller than the capacitance of the parasitic capacitor C1X in the nitride semiconductor device 10X of the comparative example. Thus, the capacitance of each of the parasitic capacitors C1 and C2 is decreased. When the nitride semiconductor device 10 of the present embodiment undergoes switching, the gate voltage applied to the gate electrode 24 allows for high-speed charging and discharging of the parasitic capacitors C1 and C2. This allows for high-speed switching of the nitride semiconductor device 10.

### Method for Manufacturing Nitride Semiconductor Device

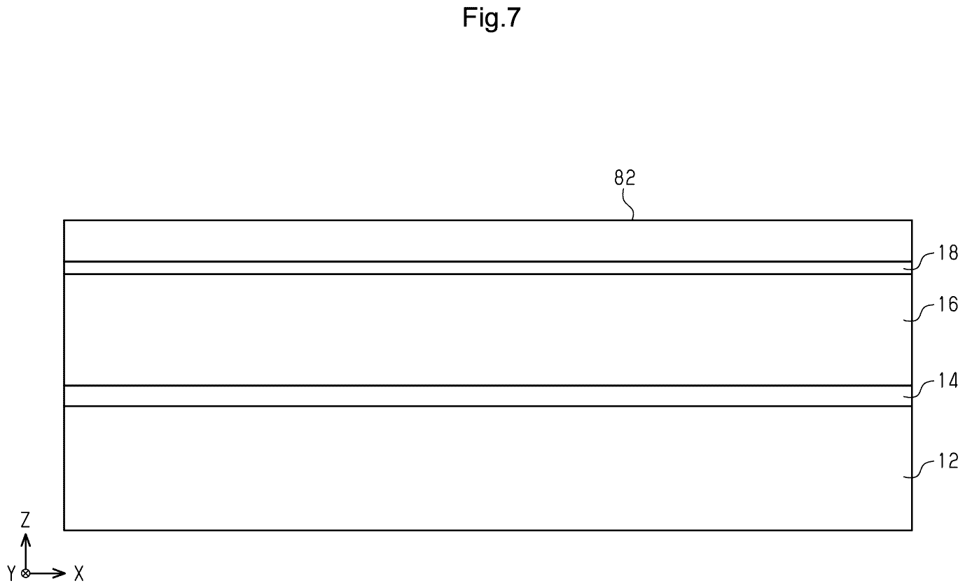

An exemplary method for manufacturing the nitride semiconductor device 10 will now be described with reference to FIGS. 7 to 18. In FIGS. 7 to 18, same reference characters are given to those elements that are the same as the corresponding elements in FIGS. 2 and 3.

As shown in FIG. 7, the method for manufacturing the nitride semiconductor device 10 includes sequentially forming the buffer layer 14, the electron transit layer 16, the electron supply layer 18, and a nitride semiconductor layer 82 on the semiconductor substrate 12. The semiconductor substrate 12 is, for example, a Si substrate. The nitride semiconductor layer 82 is, for example, a gallium nitride (GaN) layer. The buffer layer 14, the electron transit layer 16, the electron supply layer 18, and the nitride semiconductor layer 82 undergo epitaxial growth through, for example, a metal organic chemical vapor deposition (MOCVD) process.

The buffer layer 14 may be a multilayer buffer layer. The multilayer buffer layer includes an AlN layer (first buffer layer), which is formed on the semiconductor substrate 12, and a graded AlGaN layer (second buffer layer), which is formed on the AlN layer. The graded AlGaN layer may be formed by stacking three AlGaN layers respectively having Al compositions of 75%, 50%, and 25% from the side closer to the AlN layer.

The electron transit layer 16 formed on the buffer layer 14 may be a GaN layer. The electron supply layer 18 formed on the electron transit layer 16 may be an AlGaN layer. Therefore, the electron supply layer 18 is composed of a nitride semiconductor having a larger band gap than the electron transit layer 16.

The nitride semiconductor layer 82 formed on the electron supply layer 18 may include magnesium as an acceptor impurity. The doping of magnesium is performed while growing the nitride semiconductor layer 82 on the electron supply layer 18 to form the nitride semiconductor layer 82 containing the acceptor impurity. In one example, the nitride semiconductor layer 82 may contain magnesium (Mg), as an impurity, at a concentration in a range from 1×10¹⁸ cm⁻³ to 1×10²⁰ cm⁻³.

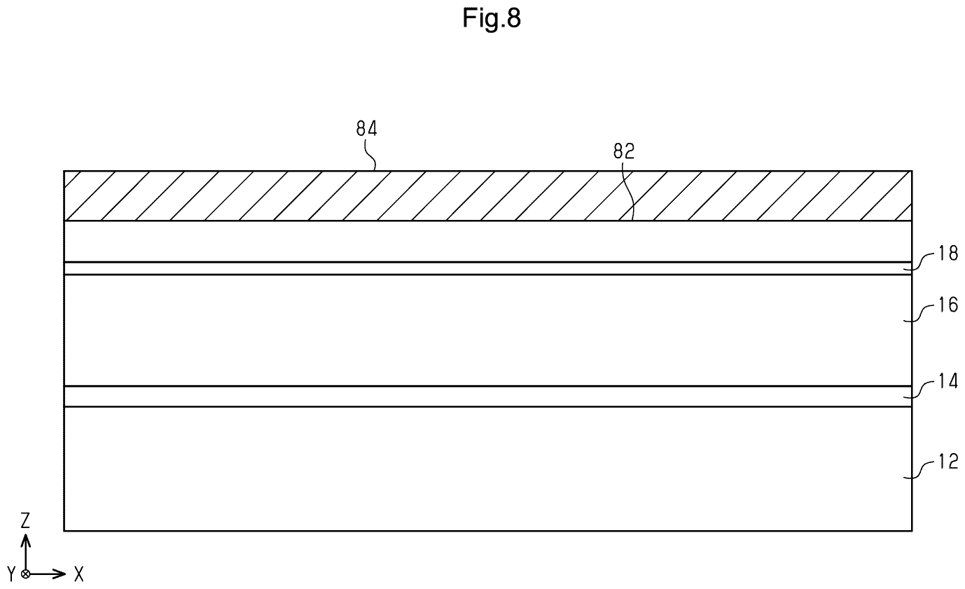

As shown in FIG. 8, the method for manufacturing the nitride semiconductor device 10 includes forming a first metal layer 84. In one example, the first metal layer 84 may be formed on the nitride semiconductor layer 82 through a sputtering process. In one example, the first metal layer 84 may be a TiN layer.

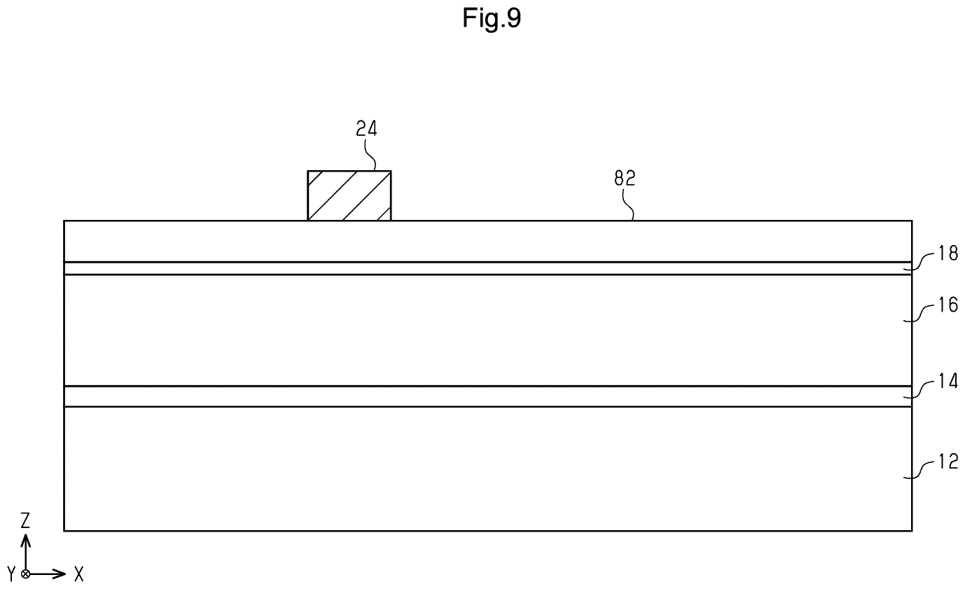

As shown in FIG. 9, the method for manufacturing the nitride semiconductor device 10 includes forming the gate electrode 24. In one example, the gate electrode 24 is formed by selectively removing the first metal layer 84 shown in FIG. 8 through lithography and etching.

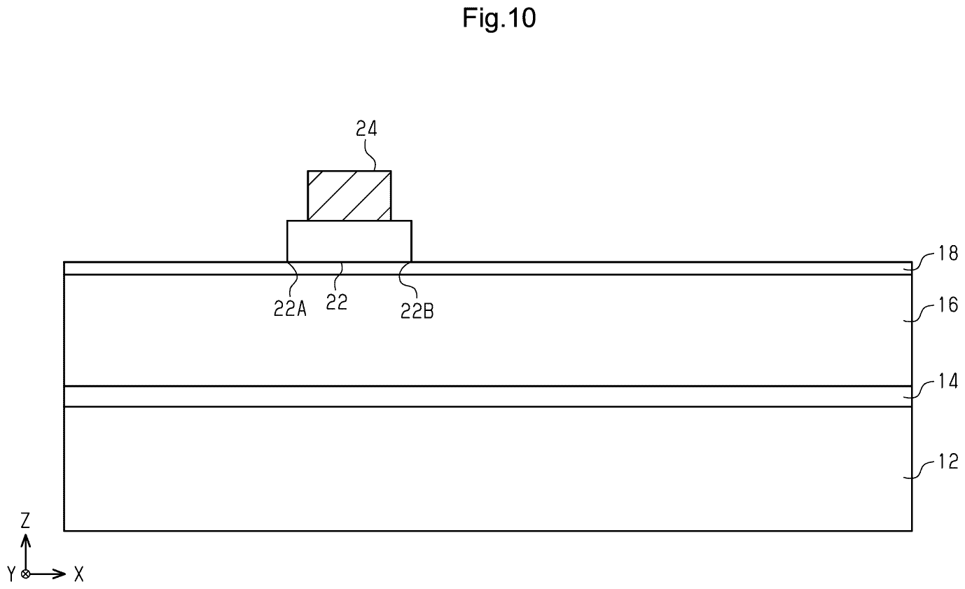

As shown in FIG. 10, the method for manufacturing the nitride semiconductor device 10 includes forming the gate layer 22. In one example, the gate layer 22 is formed by selectively removing the nitride semiconductor layer 82, shown in FIG. 9, through lithography and etching.

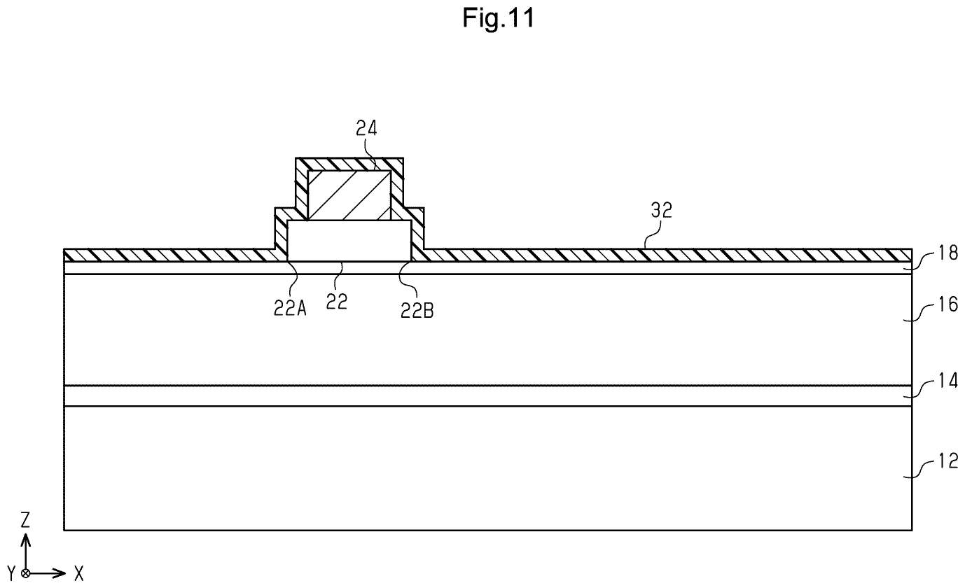

As shown in FIG. 11, the method for manufacturing the nitride semiconductor device 10 includes forming the first passivation layer 32. In one example, the first passivation layer 32 may be a SiN layer formed through a low-pressure chemical vapor deposition (LPCVD) process. The first passivation layer 32 covers the electron supply layer 18, the gate layer 22, and the gate electrode 24.

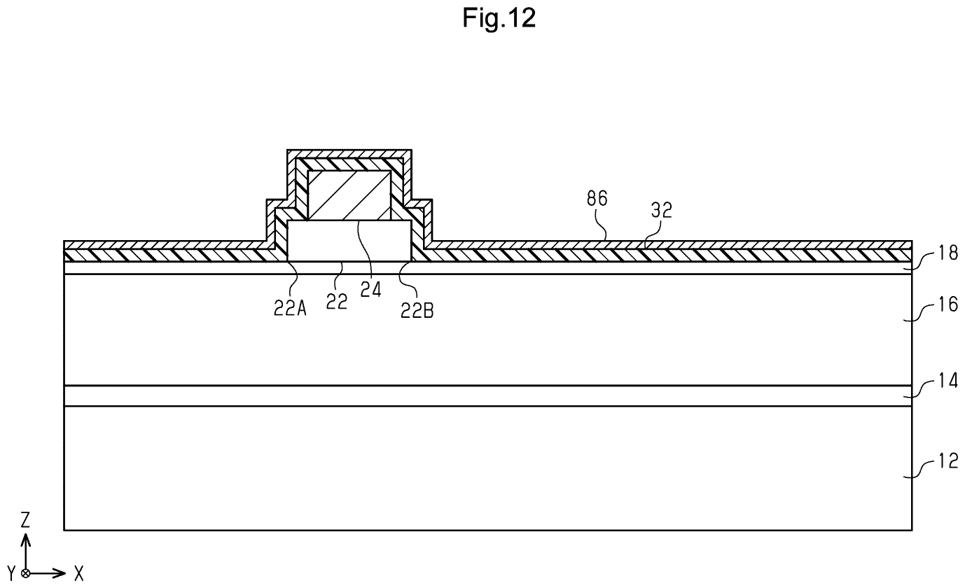

As shown in FIG. 12, the method for manufacturing the nitride semiconductor device 10 includes forming a second metal layer 86. In one example, the second metal layer 86 may be formed on the first passivation layer 32 through a sputtering process. In one example, the second metal layer 86 may be a TiN layer.

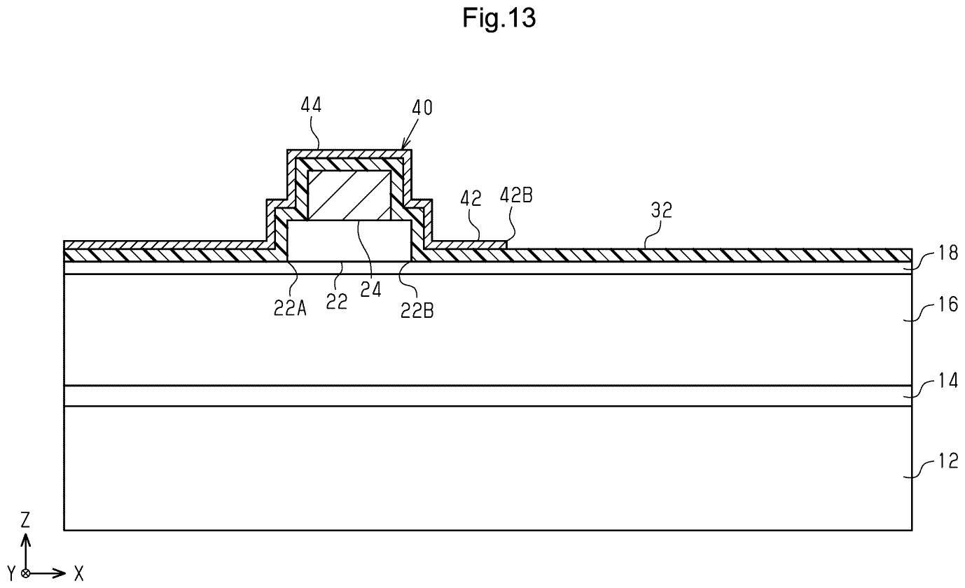

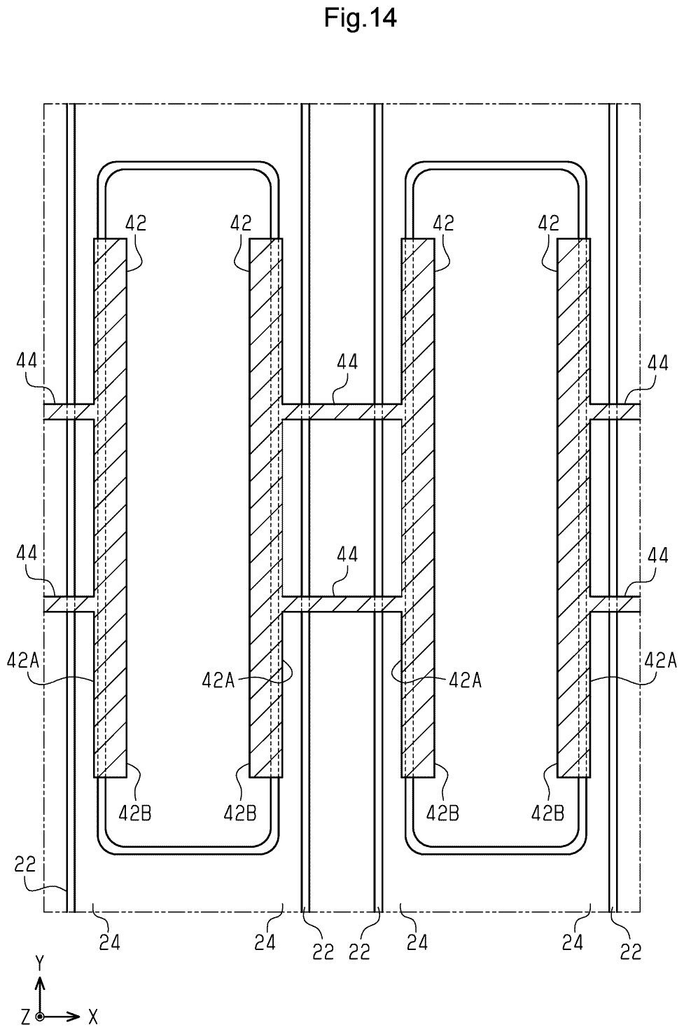

As shown in FIGS. 13 and 14, the method for manufacturing the nitride semiconductor device 10 includes forming the first field plate electrode 40. In one example, the first field plate electrode 40 is formed by selectively removing the second metal layer 86 shown in FIG. 12 through lithography and etching. As shown in FIG. 14, the first field plate electrode 40 includes plate bodies 42 extending in the Y-axis direction, and connectors 44 connecting adjacent ones of the plate bodies 42 in the X-axis direction.

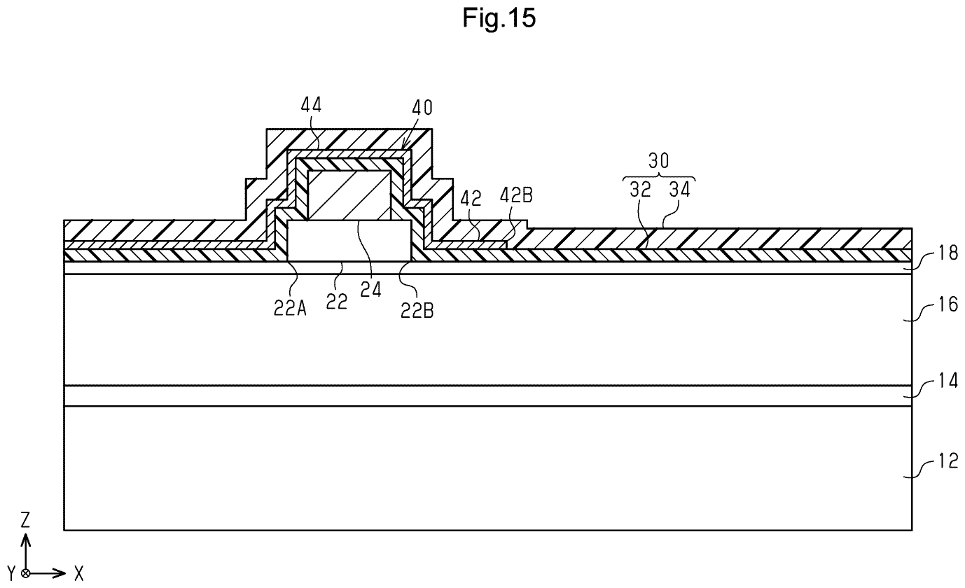

As shown in FIG. 15, the method for manufacturing the nitride semiconductor device 10 includes forming the second passivation layer 34. In one example, the second passivation layer 34 may be a SiN layer formed through a LPCVD process. The second passivation layer 34 covers the first passivation layer 32 and the first field plate electrode 40.

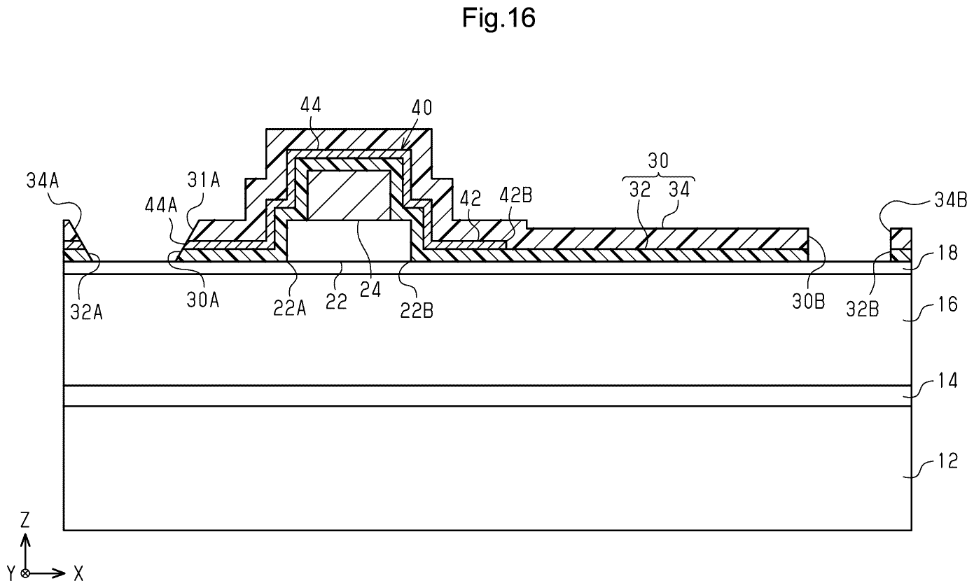

As shown in FIG. 16, the method for manufacturing the nitride semiconductor device 10 includes forming the source opening 30A and the drain opening 30B in the passivation layer 30. In one example, the source opening 30A and the drain opening 30B are formed by selectively removing the passivation layer 30 through lithography and etching. The source opening 30A is defined by the wall surface 31A that is an inclined surface inclined with respect to the Z-axis direction, which is the stacking direction of the first passivation layer 32 and the second passivation layer 34. The formation of the source opening 30A forms the connector end surface 44A of the connector 44, which is exposed from the wall surface 31A of the source opening 30A.

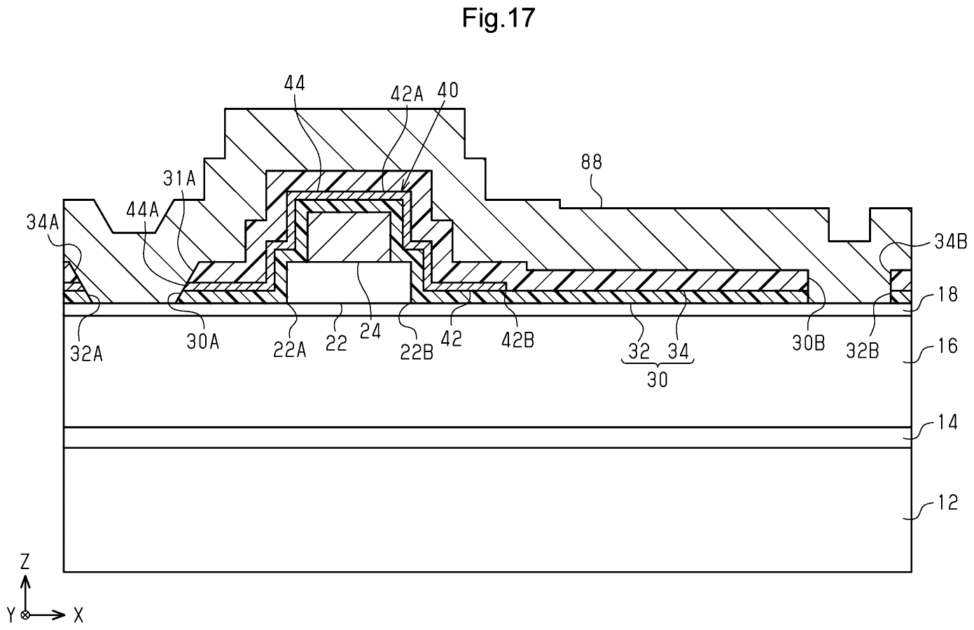

As shown in FIG. 17, the method for manufacturing the nitride semiconductor device 10 includes forming a third metal layer 88. In one example, the third metal layer 88 is formed on the passivation layer 30 through a sputtering process. The third metal layer 88 fills the source opening 30A of the passivation layer 30 and the drain opening 30B. In one example, the third metal layer 88 may be a TiN layer. The third metal layer 88 is electrically connected to the connector end surface 44A of the connector 44, which is exposed from the wall surface 31A of the source opening 30A.

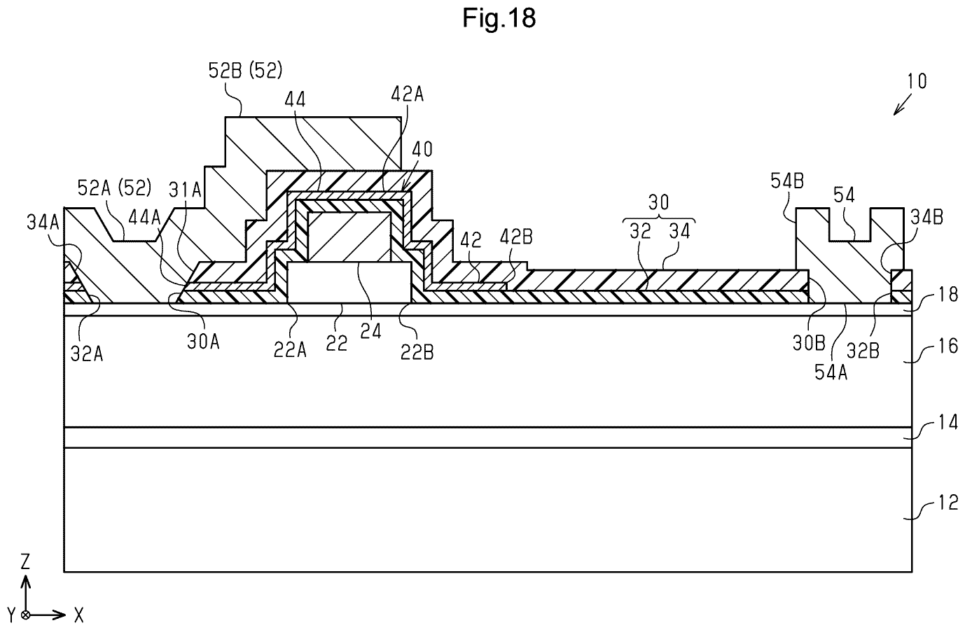

As shown in FIG. 18, the method for manufacturing the nitride semiconductor device 10 includes forming the source electrode 52 and the drain electrode 54. In one example, the source electrode 52 and the drain electrode 54 are formed by selectively removing the third metal layer 88 shown in FIG. 17 through lithography and etching. The nitride semiconductor device 10 shown in FIG. 2 is obtained through the steps described above.

### Advantages of Embodiment

The nitride semiconductor device 10 in accordance with the embodiment has the advantages described below.

(1) The nitride semiconductor device 10 includes the first passivation layer 32, which covers the electron supply layer 18, the gate layer 22, and the gate electrode 24, and the first field plate electrode 40, which is arranged on the first passivation layer 32. The first field plate electrode 40 includes the plate body 42 and the connector 44, which electrically connects the plate body 42 and the source electrode 52. The plate body 42 is at least partially arranged in a region between the gate electrode 24 and the drain electrode 54 in plan view, and extends in the Y-axis direction, which is orthogonal to the X-axis direction. The connector 44 is located above the gate electrode 24 and between the plate body 42 and the source electrode 52, has a width in the Y-axis direction, and extends in the X-axis direction to connect the plate body 42 and the source electrode 52.

The plate body 42 of the first field plate electrode 40, which is arranged on the first passivation layer 32, covers the second end 22B of the gate layer 22 located toward the drain electrode 54. Thus, the plate body 42 mitigates electric field concentration in the vicinity of the end of the gate layer 22.

(2) In the nitride semiconductor device 10 in accordance with the embodiment, in order to reduce the on resistance, for example, the distance is shortened between the source electrode 52 and the drain electrode 54. The plate body 42 of the first field plate electrode 40 is arranged on the first passivation layer 32, which covers the electron supply layer 18, the gate layer 22, and the gate electrode 24. The first passivation layer 32 is thinner than the second passivation layer 34, which forms the passivation layer 30 with the first passivation layer 32. This allows for mitigation of electric field concentration, which occurs when reducing the distance between the source electrode 52 and the drain electrode 54.

(3) The thickness T40 of the first field plate electrode 40 is less than the thickness T32 of the first passivation layer 32. Further, the thickness T40 of the first field plate electrode 40 is less than the thickness T52 of the source electrode 52. Thus, the decrease in thickness of the first passivation layer 32 resulting from over-etching when forming the first field plate electrode 40 will be much less compared to the decrease in thickness of the passivation layer 30X when forming the source electrode 52 in the nitride semiconductor device 10X of the comparative example. This maintains the insulating property of the first passivation layer 32, that is, the passivation layer 30.

(4) The first field plate electrode 40 includes the connector 44. The connector 44 is located above the gate electrode 24 and between the plate body 42 and the source electrode 52, has a width in the Y-axis direction, and extends in the X-axis direction to connect the plate body 42 and the source electrode 52. The width of the connector 44 is less than the length of the plate body 42 in the Y-axis direction. Thus, the first field plate electrode 40 faces the gate electrode 24 over a smaller area than in the nitride semiconductor device 10X of the comparative example in which the plate body 42 and the source electrode 52 are connected in the same manner. The parasitic capacitor C2 has a capacitance corresponding to the area of the connector 44 facing the gate electrode 24. The passivation layer 30 is increased in thickness so that the parasitic capacitor C1 formed between the gate electrode 24 and the source electrode 52 has a capacitance that is smaller than the capacitance of the parasitic capacitor C1X in the nitride semiconductor device 10X of the comparative example. The combined capacitance of the parasitic capacitors C1 and C2 is smaller than the capacitance of the parasitic capacitor C1X in the nitride semiconductor device 10X of the comparative example. Thus, the capacitance of each of the parasitic capacitors C1 and C2 is decreased. When the nitride semiconductor device 10 of the present embodiment undergoes switching, the gate voltage applied to the gate electrode 24 allows for high-speed charging and discharging of the parasitic capacitors C1 and C2. This allows for high-speed switching of the nitride semiconductor device 10.

### Modified Examples

The above embodiments may be modified as described below. The modified examples described below may be combined as long as there is no technical contradiction. In the modified examples described hereafter, same reference characters are given to those components that are the same as the corresponding components of the above embodiments. Such components will not be described in detail.

The structure of the nitride semiconductor device 10 may be changed.

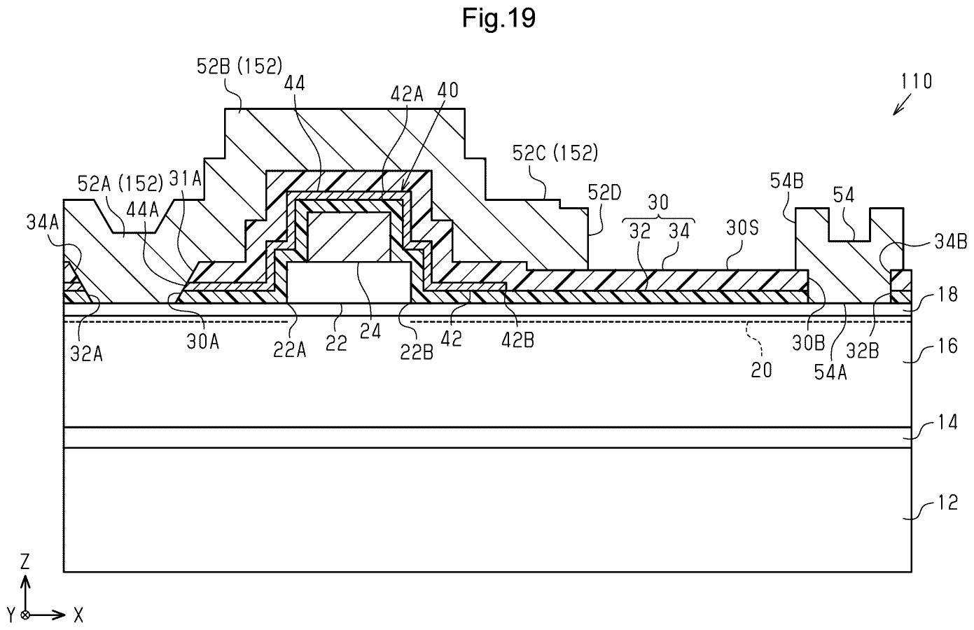

As shown in FIG. 19, a nitride semiconductor device 110 of a modified example may include a source electrode 152. The source electrode 152 includes a field plate 52C. The field plate 52C extends toward the drain electrode 54. In detail, the source electrode 152 includes the contact 52A, which is embedded in the source opening 30A, and the extension 52B, which is located near the source opening 30A. The field plate 52C extends from the extension 52B toward the drain electrode 54.

The field plate 52C covers the gate layer 22 and the gate electrode 24 in plan view. The field plate 52C includes an end 52D located toward the drain electrode 54 at a position closer to the drain electrode 54 than the second end 42B of the plate body 42, which is the end of the first field plate electrode 40 located toward the drain electrode 54.

The nitride semiconductor device 110 of the modified example mitigates electric field concentration in the vicinity of the ends of the gate electrode 24 and the gate layer 22 with the first field plate electrode 40. The nitride semiconductor device 110 further mitigates electric field concentration in the vicinity of the ends of the gate electrode 24 and the gate layer 22 with the field plate 52C. This increases the breakdown voltage of the nitride semiconductor device 110 of the modified example. The nitride semiconductor device 110 of the modified example allows the distance between the source electrode 152 and the drain electrode 54 to be shortened thereby decreasing the on resistance. The field plate 52C extends from the extension 52B of the source electrode 152 toward the drain electrode 54. Thus, the capacitance of the parasitic capacitor formed with the gate electrode 24 does not increase. This allows the nitride semiconductor device 110 to undergo high-speed switching.

In the nitride semiconductor device 110 of the modified example, the passivation layer 30, which covers the gate layer 22 and the gate electrode 24, does not have to be decreased in thickness. In detail, the second passivation layer 34, which covers the first passivation layer 32, may be increased in thickness. Thus, the insulating property of the passivation layer 30 will be maintained even if the second passivation layer 34 is subject to over-etching when forming the field plate 52C of the source electrode 152. This limits decreases in the breakdown voltage.

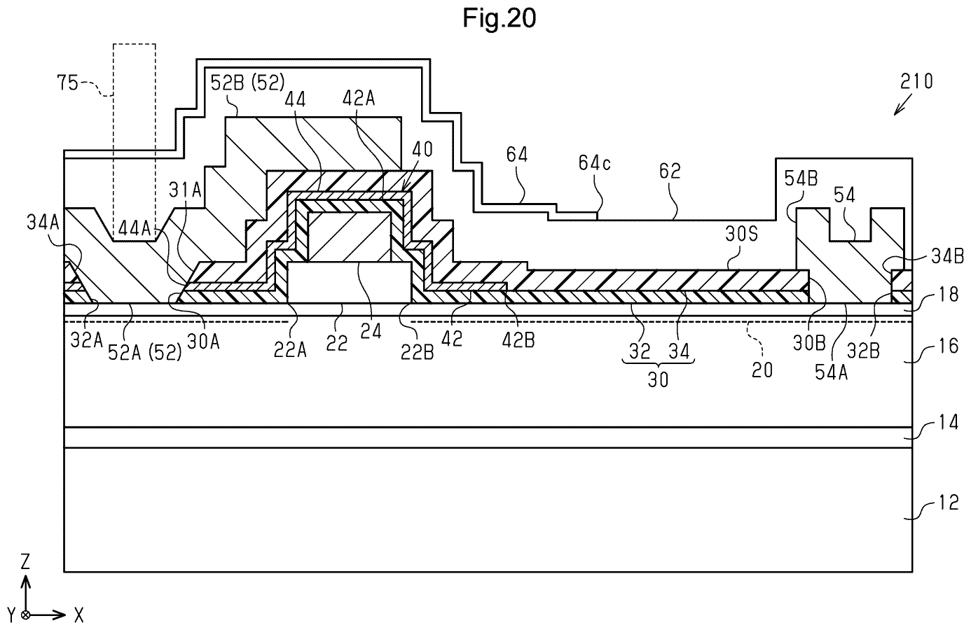

As shown in FIG. 20, a nitride semiconductor device 210 of the modified example includes a third passivation layer 62 covering the source electrode 52, and a second field plate electrode 64 arranged on the third passivation layer 62. The third passivation layer 62 covers the source electrode 52, the drain electrode 54, and the second passivation layer 34 of the passivation layer 30. The second field plate electrode 64 extends from immediately above the source electrode 52 toward the drain electrode 54.

The second field plate electrode 64 is electrically connected to the source electrode 52. More specifically, the second field plate electrode 64 is electrically connected to the via interconnect 75, which is connected to the source electrode 52. In one example, the via interconnect 75 extends through the second field plate electrode 64 and connects to the source electrode 52. The second field plate electrode 64 is at least partially arranged in a region between the gate layer 22 and the drain electrode 54 in plan view. The second field plate electrode 64 includes an end 64c located toward the drain electrode 54 at a position closer to the drain electrode 54 than the second end 42B of the plate body 42, which is the end of the first field plate electrode 40 located toward the drain electrode 54. The second field plate electrode 64 is thinner than the source electrode 52. In one example, the second field plate electrode 64 has the same thickness as the first field plate electrode 40. The second field plate electrode 64 may be thicker than the first field plate electrode 40 or thinner than the first field plate electrode 40.

The nitride semiconductor device 210 of the modified example mitigates electric field concentration in the vicinity of the ends of the gate electrode 24 and the gate layer 22 with the first field plate electrode 40 and the second field plate electrode 64. This increases the breakdown voltage of the nitride semiconductor device 210 of the modified example. The nitride semiconductor device 210 of the modified example shortens the distance between the source electrode 52 and the drain electrode 54 and decreases the on resistance. The second field plate electrode 64 is arranged on the third passivation layer 62, which covers the source electrode 52. Thus, the capacitance of the parasitic capacitor formed with the gate electrode 24 does not increase. This allows the nitride semiconductor device 210 to undergo high-speed switching.

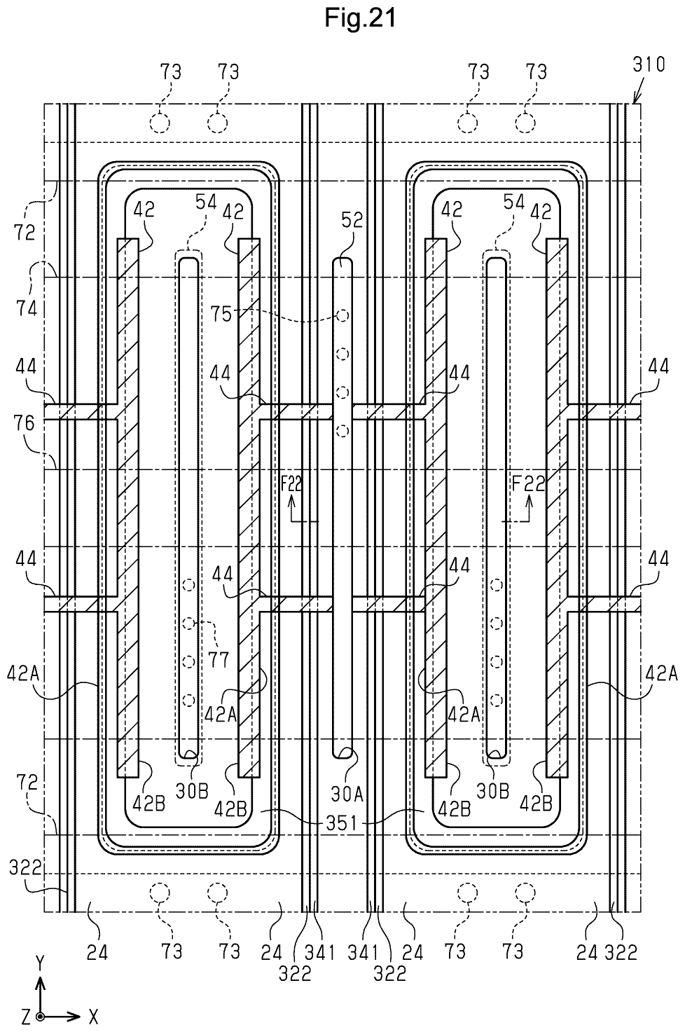

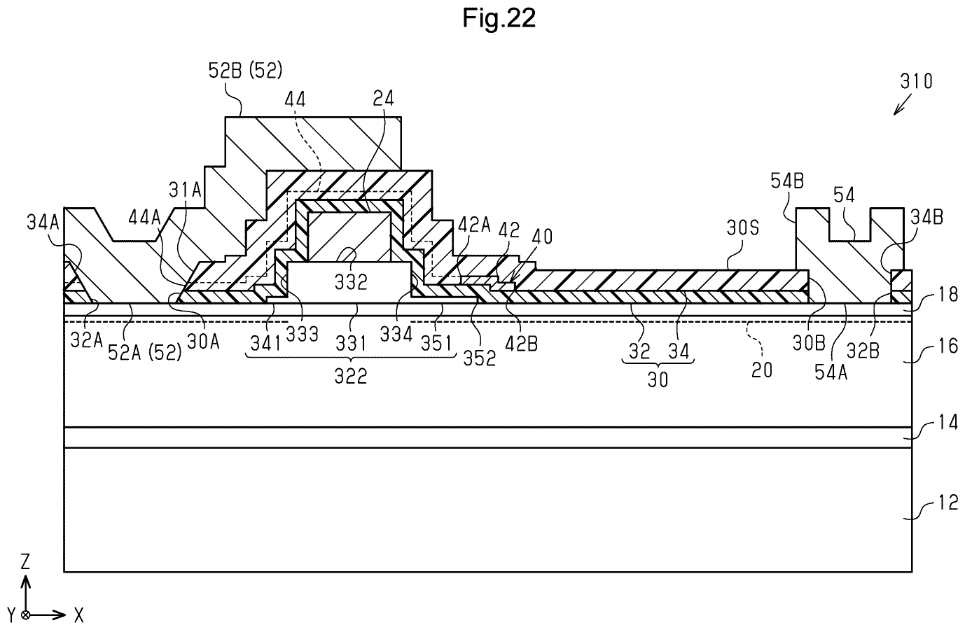

As shown in FIGS. 21 and 22, a nitride semiconductor device 310 of the modified example includes a gate layer 322. The gate layer 322 includes a ridge 331, a first extension 341 extending from one end of the ridge 331, and a second extension 351 extending from an opposite end of the ridge 331. The ridge 331, the first extension 341, and the second extension 351 form a stepped structure of the gate layer 322.

The ridge 331 corresponds to the relatively thick part of the gate layer 322. The gate electrode 24 is entirely in contact with an upper surface 332 of the ridge 331. The ridge 331 may have a rectangular or trapezoidal cross section taken along an XZ plane in FIG. 21. The ridge 331 may have a thickness, for example, in the range from 100 nm to 200 nm, inclusive. The thickness of the ridge 331 is the distance from the upper surface 332 to the lower surface (lower surface of gate layer 322 contacting electron supply layer 18) of the ridge 331. The thickness of the ridge 331 (gate layer 322) may be determined by considering various parameters such as the gate breakdown voltage.

The first extension 341 extends from a source side surface 333 of the ridge 331 toward the source opening 30A of the passivation layer 30. The second extension 351 extends from a drain side surface 334 of the ridge 331 toward the drain opening 30B of the passivation layer 30. In the example of FIGS. 21 and 22, the second extension 351 extends over a greater length from the ridge 331 than the first extension 341. The first extension 341 and the second extension 351 may have the same length. The first extension 341 may have a thickness, for example, in a range from 10 nm to 30 nm, inclusive. In the direction from the ridge 331 toward the source opening 30A, the first extension 341 may have a width, for example, in a range from 0.2 μm to 0.3 μm, inclusive. The second extension 351 may have a thickness, for example, in a range from 10 nm to 30 nm, inclusive. In the direction from the ridge 331 toward the drain opening 30B, the second extension 351 may have a width, for example, in a range from 0.2 μm to 0.6 μm, inclusive. The first extension 341 and the second extension 351 may have the same thickness. The first extension 341 and the second extension 351 have the same thickness as long as the difference in thickness between the first extension 341 and the second extension 351 is 10% or less of the thickness of the first extension 341.

The second extension 351 has an end 352 located toward the drain electrode 54, and the plate body 42 of the first field plate electrode 40 covers the end 352. The first end 42A of the plate body 42 may overlap the second extension 351 in plan view. The second end 42B of the plate body 42 may be located between the end 352 of the second extension 351 and the drain electrode 54 in plan view.

In the nitride semiconductor device 310 of the modified example, the first extension 341 and the second extension 351 reduce the hole density at the interface between the gate layer 322 and the electron supply layer 18. This avoids band bending of the electron supply layer 18 that would be caused by hole accumulation and limits increases in the gate leakage current. The plate body 42 of the first field plate electrode 40 covers the end 352 of the second extension 351 located toward the drain electrode 54. This limits electric field concentration in the vicinity of the end 352 of the gate layer 322.

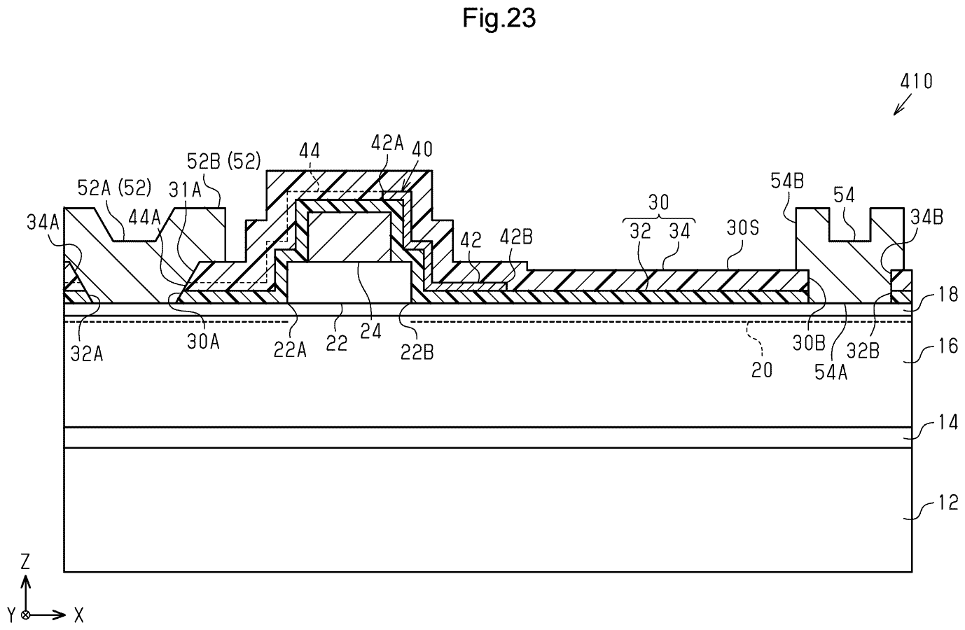

FIG. 23 shows a nitride semiconductor device 410 of a modified example. The source electrode 52 is separated from the gate layer 22 and the gate electrode 24 in plan view.

The source electrode 52 and the drain electrode 54 do not have to contact the electron supply layer 18 in the same manner as the above embodiment. For example, the electron supply layer 18 may include a source opening and a drain opening. The contact 52A of the source electrode 52 is arranged in the source opening 30A of the passivation layer 30 and the source opening of the electron supply layer 18. This structure also allows the source electrode 52 to contact the electron supply layer 18. The contact 54A of the drain electrode 54 is arranged in the drain opening 30B of the passivation layer 30 and the drain opening of the electron supply layer 18. This structure also allows the drain electrode 54 to contact the electron supply layer 18. The source opening and the drain opening of the electron supply layer 18 may be located between the source electrode 52 and the electron transit layer 16 and between the drain electrode 54 and the electron transit layer 16.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The Z-axis direction as referred to in this specification does not necessarily have to be the vertical direction and does not necessarily have to fully coincide with the vertical direction. Accordingly, in the structures disclosed above (e.g., structure shown in FIG. 2), upward and downward in the Z-axis direction as referred to in this specification is not limited to upward and downward in the vertical direction. For example, the X-axis direction may be the vertical direction. Alternatively, the Y-axis direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### Clause 1

A nitride semiconductor device, including:
an electron transit layer (16) composed of a nitride semiconductor;
an electron supply layer (18) arranged on the electron transit layer (16) and composed of a nitride semiconductor having a larger band gap than the electron transit layer (16);
a gate layer (22, 322) arranged on the electron supply layer (18) and composed of a nitride semiconductor containing an acceptor impurity;
a gate electrode arranged on the gate layer (22, 322);
a first passivation layer (32) covering the electron supply layer (18), the gate layer (22, 322), and the gate electrode, and including a first source opening (32A) and a first drain opening (32B) separated from each other in a first direction (X) and located at opposite sides of the gate layer (22, 322) in the first direction (X);
a source electrode (52, 152) contacting the electron supply layer (18) in the first source opening (32A);
a drain electrode (54) contacting the electron supply layer (18) in the first drain opening (32B);
a first field plate electrode (40) arranged on the first passivation layer (32);
a second passivation layer (34) covering the first passivation layer (32) and the first field plate electrode (40), where
the first field plate electrode (40) includes a plate body (42) separated from the source electrode (52, 152) in the first direction (X), and a connector (44) electrically connecting the plate body (42) and the source electrode (52, 152),
the plate body (42) is at least partially arranged in a region between the gate electrode and the drain electrode (54) in plan view, and extends in a second direction (Y) that is orthogonal to the first direction (X) in plan view,
the connector (44) is located above the gate electrode and between the plate body (42) and the source electrode (52, 152), has a width in the second direction (Y), and extends in the first direction (X) to connect the plate body (42) and the source electrode (52, 152), and
the width of the connector (44) is less than a length of the plate body (42) in the second direction (Y).

### Clause 2

The nitride semiconductor device according to clause 1, where the first field plate electrode (40) is thinner than the source electrode (52).

### Clause 3

The nitride semiconductor device according to clauses 1 or 2, where the first passivation layer (32) is thinner than the second passivation layer (34).

### Clause 4

The nitride semiconductor device according to clauses 1 or 2, where the first field plate electrode (40) is thinner than the second passivation layer (34).

### Clause 5

The nitride semiconductor device according to any one of clauses 1 to 4, where the connector (44) has an area that is less than or equal to one-tenth of an area of the plate body (42).

### Clause 6

The nitride semiconductor device according to any one of clauses 1 to 5, where the width of the connector (44) is less than or equal to one-fiftieth of the length of the plate body (42) in the second direction (Y).

### Clause 7

The nitride semiconductor device according to any one of clauses 1 to 6, where the width of the connector (44) is in a range from 5 μm to 10 μm, inclusive.

### Clause 8

The nitride semiconductor device according to any one of clauses 1 to 7, where
the source electrode (152) is arranged on the second passivation layer (34) and includes a field plate (52C) extending toward the drain electrode (54),
the field plate (52C) covers the gate electrode in plan view, and
an end (52D) of the field plate (52C) located toward the drain electrode (54) is closer to the drain electrode (54) than an end of the first field plate electrode (40) located toward the drain electrode (54).

### Clause 9

The nitride semiconductor device according to any one of clauses 1 to 8, further including:
a third passivation layer (62) covering the source electrode (52); and
a second field plate electrode (64) arranged on the third passivation layer (62) and electrically connected to the source electrode (52), where
the second field plate electrode (64) is at least partially arranged in a region between the gate layer (22) and the drain electrode (54) in plan view, and
an end (64c) of the second field plate electrode located toward the drain electrode (54) is closer to the drain electrode (54) than an end (42B) of the first field plate electrode (40) located toward the drain electrode (54).

### Clause 10

The nitride semiconductor device according to any one of clauses 1 to 9, where
the second passivation layer (34) includes a second source opening (34A) that is in communication with the first source opening (32A),
the first source opening (32A) and the second source opening (34A) form a source opening (30A) that includes a wall surface (31A) from which the connector (44) is exposed,
the wall surface (31A) of the source opening (30A) includes an inclined surface that is inclined with respect to a thickness direction of the first passivation layer (32) and the second passivation layer (34),
the connector (44) includes a connector end surface (44A) connected to the source electrode (52), and
the connector end surface (44A) is inclined in conformance with the inclined surface.

### Clause 11

The nitride semiconductor device according to any one of clauses 1 to 10, where the plate body (42) overlaps part of the gate electrode (24).

### Clause 12

The nitride semiconductor device according to any one of clauses 1 to 11, where an area of a region in which the plate body (42) and the gate electrode (24) overlap is smaller than an area of a region in which the plate body (42) and the gate electrode (24) do not overlap.

### Clause 13

The nitride semiconductor device according to any one of clauses 1 to 12, where the connector (44) is one of multiple connectors separated from each other in the second direction (Y).

### Clause 14

The nitride semiconductor device according to any one of clauses 1 to 13, where
the gate layer (322) includes
   a ridge (331) on which the gate electrode is arranged,
   a first extension (341) extending from the ridge toward the source electrode (52), and
   a second extension (351) extending from the ridge toward the drain electrode (54), and
the plate body (42) covers an end (352) of the second extension located toward the drain electrode (54).

### Clause 15

The nitride semiconductor device according to clause 8, where
the source electrode (52) includes a contact (52A) filling the first source opening (32A), and an extension (52B) extending to the second passivation layer (34), and
the field plate (52C) extends from the extension (52B) toward the drain electrode (54).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

What is claimed is:

1. A nitride semiconductor device, comprising:
an electron transit layer composed of a nitride semiconductor;
an electron supply layer arranged on the electron transit layer and composed of a nitride semiconductor having a larger band gap than the electron transit layer;
a gate layer arranged on the electron supply layer and composed of a nitride semiconductor containing an acceptor impurity;
a gate electrode arranged on the gate layer;
a first passivation layer covering the electron supply layer, the gate layer, and the gate electrode, and including a first source opening and a first drain opening separated from each other in a first direction and located at opposite sides of the gate layer in the first direction;
a source electrode contacting the electron supply layer in the first source opening;
a drain electrode contacting the electron supply layer in the first drain opening;
a first field plate electrode arranged on the first passivation layer;
a second passivation layer covering the first passivation layer and the first field plate electrode, wherein
the first field plate electrode includes a plate body separated from the source electrode in the first direction, and a connector electrically connecting the plate body and the source electrode,
the plate body is at least partially arranged in a region between the gate electrode and the drain electrode in plan view, and extends in a second direction that is orthogonal to the first direction in plan view,
the connector is located above the gate electrode and between the plate body and the source electrode, has a width in the second direction, and extends in the first direction to connect the plate body and the source electrode, and
the width of the connector is less than a length of the plate body in the second direction.

2. The nitride semiconductor device according to claim 1, wherein the first field plate electrode is thinner than the source electrode.

3. The nitride semiconductor device according to claim 1, wherein the first passivation layer is thinner than the second passivation layer.

4. The nitride semiconductor device according to claim 1, wherein the first field plate electrode is thinner than the second passivation layer.

5. The nitride semiconductor device according to claim 1, wherein the connector has an area that is less than or equal to one-tenth of an area of the plate body.

6. The nitride semiconductor device according to claim 1, wherein the width of the connector is less than or equal to one-fiftieth of the length of the plate body in the second direction.

7. The nitride semiconductor device according to claim 1, wherein the width of the connector is in a range from 5 μm to 10 μm, inclusive.

8. The nitride semiconductor device according to claim 1, wherein
the source electrode is arranged on the second passivation layer and includes a field plate extending toward the drain electrode,
the field plate covers the gate electrode in plan view, and
an end of the field plate located toward the drain electrode is closer to the drain electrode than an end of the first field plate electrode located toward the drain electrode.

9. The nitride semiconductor device according to claim 1, further comprising:
a third passivation layer covering the source electrode; and
a second field plate electrode arranged on the third passivation layer and electrically connected to the source electrode, wherein
the second field plate electrode is at least partially arranged in a region between the gate layer and the drain electrode in plan view, and
an end of the second field plate electrode located toward the drain electrode is closer to the drain electrode than an end of the first field plate electrode located toward the drain electrode.

10. The nitride semiconductor device according to claim 1, wherein
the second passivation layer includes a second source opening that is in communication with the first source opening,
the first source opening and the second source opening form a source opening that includes a wall surface from which the connector is exposed,
the wall surface of the source opening includes an inclined surface that is inclined with respect to a thickness direction of the first passivation layer and the second passivation layer,
the connector includes a connector end surface connected to the source electrode, and
the connector end surface is inclined in conformance with the inclined surface.

11. The nitride semiconductor device according to claim 1, wherein the plate body overlaps part of the gate electrode.

12. The nitride semiconductor device according to claim 1, wherein an area of a region in which the plate body and the gate electrode overlap is smaller than an area of a region in which the plate body and the gate electrode do not overlap.

13. The nitride semiconductor device according to claim 1, wherein the connector is one of multiple connectors separated from each other in the second direction.

14. The nitride semiconductor device according to claim 1, wherein
the gate layer includes:
a ridge on which the gate electrode is arranged;
a first extension extending from the ridge toward the source electrode; and
a second extension extending from the ridge toward the drain electrode, and
the plate body covers an end of the second extension located toward the drain electrode.
